(19) United States
(12) Patent Application Publication
(10) Pub. No.: US 2024/0231135 A1
(43) Pub. Date: Jul. 11, 2024

(54) OPTOELECTRONIC ARRANGEMENT AND METHOD

(71) Applicant: ams-OSRAM International GmbH, Regensburg (DE)

(72) Inventor: Jens Ebbecke, Helchenbach (DE)

(21) Appl. No.: 18/570,929

(22) PCT Filed: Jun. 18, 2021
(86) PCT No.: PCT/EP2021/066703

§ 371 Date: Dec. 15, 2023

(51) Int. Cl. G02F 1/125; H01L 33/62; H03H 9/02

(52) U.S. Cl. CPC G02F 1/125; H01L 33/62; H03H 9/02968

(57) ABSTRACT

In an embodiment an optoelectronic arrangement includes an optoelectronic component having a layer stack including an active area arranged between a layer of a first conductive type and a layer of a second conductive type, a substrate configured to generate an alternating electrical field at a surface of the substrate, the alternating electrical field having opposing field components and at least one first excitation element arranged on or within the substrate, wherein the optoelectronic component is arranged on the substrate such that the opposing field components of the alternating electrical field are substantially perpendicular to respective layers of the layer stack.

### CROSS-REFERENCE TO RELATED APPLICATIONS

This patent application is a national phase filing under section 371 of PCT/EP2021/066703, filed Jun. 18, 2021, which is incorporated herein by reference in its entirety.

### TECHNICAL FIELD

The present invention concerns an optoelectronic arrangement. The invention also relates to a method for contactless supplying energy to an optoelectronic component, the optoelectronic component having an active area arranged between a first and a second layer of different conductivity types.

### BACKGROUND

Optoelectronic components also referred to as lighting diodes or LEDs require a supply of energy for illumination. Electrical leads as well as electrical contact supplying the LED with a specific current provide such energy. Charge carriers of different conductivity taxes, namely holes and electrons are injected into respective layer of the LED, in which the diffuse towards an active area and recombine under the emission of light.

By changing the current or voltage across the optoelectronic component, one can change the brightness as well as to some extent color. However, certain application or environment might be challenging with regard to provide the required current. For example, in case of explosive gases, a flowing current can create a risk of sparking. In such environment, an electrical system must be extremely well encapsulated, which is a technical problem. In other applications, access to the optoelectronic component or its electrical contacts might be limited.

### SUMMARY

Embodiments provide an optoelectronic component without providing current thereto.

The concept is based on the idea that energy transport can be achieved by electric or magnetic field and in particular alternating electric field. Arranging an optoelectronic component in an alternating electric field such that the field lines comprise a transversal component onto the conductive layers may generate and alternating current within the optoelectronic component. In other words, the existing free charge carriers in the semiconductor material of the optoelectronic component experience an alternating electrical force causing a charger carrier movement. As a result, charge carriers are periodically induced into the active area recombining under the emission of light. Amplitude and frequency of the electrical field influences the brightness as well an energy transmission from the field into the optoelectronic component.

The energy transport by an alternating electrical field can be achieved by proper generation of the field. One example is given by capacitor plate, with the alternating field being generated in between. Arranging the optoelectronic component between two capacitor plates causes the LED to emit light by means of an applied AC voltage. These optoelectronic component does not have any electrical connections, but the thermally generated charge carriers within the optoelectronic component are brought in a half cycle of the alternating electric field into the active area of the LED, where they
where they recombine radiatively.

The inventor now proposes the use of surface acoustic waves (SAW) to generate the alternating electric field. Propagating SAW on a piezoelectric substrate are accompanied by an alternating electric field, and this field is used to provide energy for an optoelectronic component. For this purpose, a substrate is provided that is configured when being excited to generate an alternating electrical field at a surface of the substrate. An electrical field being generated may comprise potential differences in the range of a few volts, which are sufficient to induce charge carriers of an optoelectronic component into its active area causing light emission thereof.

The excitation frequency may be twofold. On the one hand, a higher frequency is generally preferable as more energy can be transported. On the other hand, charger carrier need to be generated thermally and charge carrier relaxation as well as charge carrier lifetime may limit the frequency to the range of a few kHz to a few 100 kHz. The relatively low frequency would usually require very large excitation elements. However, one may use two or more that excited the substrate with slightly different frequency resulting in a superposition of the electrical fields with its enveloping portion having a beat frequency in the above-mentioned range. Superimposing one or more electrical field also allow very high field values thus generating large potential differences in the optoelectronic component.

In some aspects, the inventor proposes an optoelectronic arrangement that includes an optoelectronic component comprising a layer stack with an active area arranged between a layer of a first conductive type and a layer of a second conductive type. The optoelectronic component is arranged on a substrate that is configured when being excited to generate an alternating electrical field at a surface of the substrate. The arrangement also comprises at least a first excitation element arranged on or within the substrate. The optoelectronic component is positioned on the substrate in such way that opposing field components of the alternating electrical field are substantially perpendicular to the respective layers of the layer stack.

In another aspect, an optoelectronic component that comprises a substrate configured to generate surface acoustic waves, SAW when being excited. An optoelectronic component comprising an active area arranged between an n-type and a p-type layer is positioned on the surface of the substrate in such way that portion of the n-type and p-type layers are substantially perpendicular to the surface of the substrate. As a result, opposing field component of the surface acoustic waves are at least partially perpendicular or transversal towards the respective surfaces of the n-tape and p-type layer, respectively.

For the purpose of the disclosure, the term “opposing field component” relate to components of the electrical field that are substantially antiparallel to each other. In an alternating electrical field, the E-vector is alternating. Propagation of the electrical field on the surface of the substrate causes the e-vector to alternate as well and two different surface positions may include e-vectors that have the same size, but are otherwise anti-parallel, thus constituting opposing field component. It should be noted that in some instances the opposing field components are understood to be those field components, which either are or at least comprise a significant portion that extends parallel to the surface of the substrate. An alternating electrical field may comprise a frequency and an associated wavelength. Likewise, superpositions of electrical fields comprise more than a single base frequency, but the resulting enveloping field can also be characterized by a beat frequency and an associated beat wavelength. Due to the superposition and the resulting beat, the associated beat frequency is usually much smaller than the base frequencies and the associated wavelength much longer.

In some aspects, the substrate is configured to generate a surface acoustic wave propagating beneath the optoelectronic component.

Some aspects concern the relationship between the wavelength of the alternating electrical field and the dimensions of the optoelectronic component. In some instances, the opposing field components are spaced apart by a distance corresponding to half of the wavelength of the alternating electrical field. Likewise, the thickness of the layer stack should have a dedicated relationship with the wavelength to ensure charge carriers are efficiently separated and the electrical field has a maximum effect on the charge carriers. In some aspects, the layer stack comprises a thickness less than a wavelength of the alternating electrical field, an in particular comprises a thickness in the range of 0.4 to 0.75 of the wavelength of the alternating electrical field. In other words, the layer stack may comprise a thickness at about half of the wavelength.

The active area of the layer stack may comprise a single or a multi-quantum well structure. The n-type doped or p-type doped layer comprise in some instances different doping profiles resulting in a desired distortion and change of the respective bandgap. In some aspects, the bandgap change and the orientation of the layer stack towards the surface of the substrate is selected such that charge carriers are concentrated in a certain area within the layer stack, preferably spaced apart from the edges. Doping the different layers of the layer stack with a dedicated profile suitable for the arrangement in accordance with the proposed principle may increase efficiency and energy transfer from the electrical field when inducing charge carriers into the active area. The material of the layer tack and the respective bandgap within the active area can be adjusted to the respective needs. The voltage induced by the alternating electrical field is large enough to induce free carriers in GaN, GaP, AlGaN, GaAs, AlGaAs materials including suitable dopant and concentration thereof.

Some other aspects concerns the material for the substrate in some aspects, the material is a piezoelectric material or comprises such properties. The substrate may be formed completely from such material with piezoelectric properties. In some other instances, the substrate includes a surface layer or a layer close to the surface with a piezoelectric material. The expression piezoelectric material is understood as a material with piezoelectric properties. Examples for piezoelectric material may be of crystalline form as well as in ceramics. It may include one of: GaPO₄, LiNbO₃, LiTaO₃, Quartz, AlPO₄, PbTiO₃, Topaz, Pb[ZrₓTi₁₋ₓ]O₃ with 0≤x≤1, KNbO₃, Ba₂NaNb₅O₅ as well as thin polycrystalline films of ZNO in the Wurtzite structure, BaTiO₃, BiFeO₃, NaNbO₃.

In some instances, a piezoelectric potential can be created in any bulk or nanostructured semiconductor crystal having non central symmetry, such as the Group III-V and II-VI materials, due to polarization of ions under applied stress and strain. This property is common to both the zincblende and wurtzite crystal structures. To first order, there is only one independent piezoelectric coefficient in zincblende, called e14, coupled to shear components of the strain. In wurtzite, there are instead three independent piezoelectric coefficients: e31, e33 and e15. The semiconductors where the strongest piezoelectricity is observed are those commonly found in the wurtzite structure, i.e. GaN, InN, AlN and ZnO. Further materials may include zincblende GaAs and InAs, under pseudomorphic strain, using Harrison's Model; zincblende GaAs and InAs, for any combination of diagonal strain components; all common III-V semiconductors in the zincblende structure using ab initio, wurtzite crystal structure GaAs, InAs, GaP and InP using Harrison's Model.

In some instances, a semiconductor material of the above can be used to subsequently grow the layer stack such that the substrate and the semiconductor form an integrated structure.

In some aspects, the arrangement comprises a second excitation element. The second excitation element is arranged on or within the substrate at some distance from the at least first excitation element with the optoelectronic component arranged in between. In some further aspects another one or two excitation elements can be arranged such that all element are located along the virtual sides of a rectangle with the optoelectronic component in between. In some instances, at least the first and second excitation elements may comprise an interdigital transducer. In this regard, the dimensions of the first and second excitation elements can be different, resulting in the generation of surface acoustic waves in the substrate having different frequencies and wavelength. When propagating beneath the optoelectronic component the SAWs superimpose.

Some other aspects concern the generation of a standing wave on the surface of the substrate and a standing surface acoustic wave. In such instances, the arrangement may comprise a reflector being arranged at a distance from the first and/or second excitation element. In some instances, the second excitation element comprises the reflector. By generating a standing surface acoustic wave, one or more the optoelectronic components can be positioned in an efficient way. For example, the active area of the layer stack may be located above or close to a node of the standing wave, with the n-type or p-type layers located above or close to the maximum amplitude of adjacent half-periods. Energy transfer may be maximized by such arrangement. Similar to the previous proposals, such standing wave may also be generated by superimposing one or more SAWs.

Another aspect is concerned with a method for contactless supplying energy to an optoelectronic component, the optoelectronic component having an active area arranged between a first and a second layer of different conductivity types. The method comprises the step of generating a surface acoustic wave on a surface of a substrate, wherein at least a portion of the electrical field of the surface acoustic wave extends above the surface and comprises a field component substantially parallel towards the surface. The surface acoustic wave is associated with a wavelength. The surface acoustic wave now exerts a force by said field component in the first and a second layer of the optoelectronic component. The force causes, charge carriers within the first and a second layer to move towards the active area during a first half-period of the wavelength and charge carriers within the first and a second layer away from the active area during a second half-period of the wavelength.

As a consequence, the induced electrical field in the optoelectronic component transfers energy into the component sufficient to induce charge carriers into the active area, in which they recombine under the emission of light. In accordance with the proposed principle, the transfer of energy takes place during a first half period of the surface acoustic wave, while during the second half period, charge carrier relaxation and thermal generation can take place. The optoelectronic component does not need electrical contacts and is supplied completely contactless.

In some aspects, the optoelectronic component can be arranged on the substrate such that the first and a second layer are substantially perpendicular towards the surface of the substrate. In such embodiment, the portion of the electrical field above the substrate's surface may comprise a component that is substantially perpendicular to the first and second layer's surface. In some other aspects, the step of generating a surface acoustic wave comprises generating a first surface acoustic wave with a first frequency and a generating a second surface acoustic wave with a second frequency that is slightly different to the first frequency. Consequently, a beat may be generated to be used to excite the charge carrier. The beat frequency may be constant but can also vary if needed. In some instances the beat signal; that is the superposition of the different SAW can comprise a sine wave, although different forms, like sawtooth, rectangular triangle and combinations thereof are possible.

It may be suitable in some aspects, that step of generating a surface acoustic wave comprises adjusting the wavelength such that only one node is located beneath the optoelectronic component. In other words, the thickness of the optoelectronic component and the frequency or wavelength of the SAW must be adjusted properly; as otherwise, the forces exerted onto the charge carriers may compensate each other reducing the efficiency of the energy transfer. In this regard, a thickness of the optoelectronic component may be in the range of a wavelength and sometimes a bit smaller than a full wavelength.

In some other aspects, a standing acoustic wave is generated. In such embodiments, the optoelectronic component could be arranged above a node of the standing wave.

The present arrangement and method are not limited to a single optoelectronic component. Rather, several components can be arranged with specific distances towards each other to be supplied with energy in accordance with the proposed principle. For example, optoelectronic component may be arranged perpendicular to each other allowing to become supplied by SAW propagating in different, i.e. perpendicular directions.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows a perspective view of an arrangement in accordance with some aspects of the present disclosure;

FIG. 2A and 2B illustrate a side view of an arrangement in accordance with some aspects of the present disclosure at different times;

FIG. 3 illustrates the situation for a SAW at a surface of a substrate illustrating the propagation of the E-field vectors in accordance with some aspects of the proposed principle;

FIG. 4 illustrate a diagram for different excitations signals, which may be suited for generating SAW in accordance with some aspects of the present disclosure;

FIG. 5 shows an exemplary embodiment for an optoelectronic device to be arranged on a surface of a piezoelectric substrate in accordance with some aspects of the present disclosure; and

FIG. 6 illustrates a method showing some aspects of the proposed concept.

### DETAILED DESCRIPTION OF ILLUSTRATIVE EMBODIMENTS

The following embodiments and examples disclose different aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the Figures can be combined with each other without further ado, without this contradicting the principle according to embodiments of the invention. Some aspects show a regular structure or form. It should be noted that in practice slight differences and deviations from the ideal form or shape may occur without, however, contradicting the inventive idea.

In addition, the individual Figures and aspects are not necessarily shown in the correct size, nor do the proportions between individual elements have to be essentially correct. Some aspects are highlighted by showing them enlarged. However, terms such as “above”, “above” “below”, “below” “larger”, “smaller” and the like are correctly represented with regard to the elements in the Figures. So it is possible to deduce such relations between the elements based on the Figures.

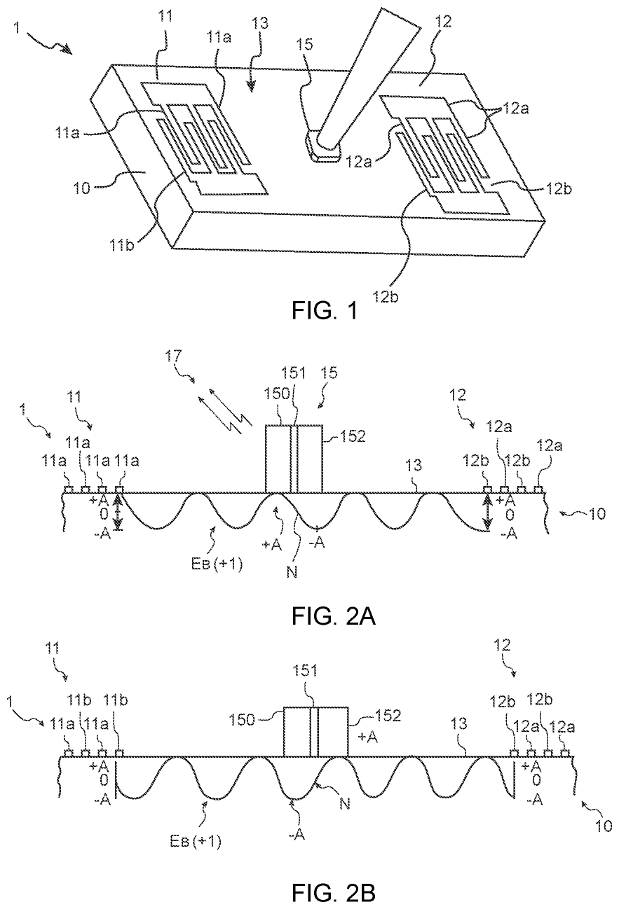

FIG. 1 shows perspective view of an arrangement in accordance with some aspects of the present disclosure. The arrangement 1 comprises a substrate 10, here of rectangular shape with two interdigital transducers 11 and 12 arranged on the top surface 13 of the substrate. The substrate 10 comprises a piezoelectric material that is capable of producing surface acoustic waves when being excited. The first transducer 11 is configured to excite the substrate with a first frequency f1, while the second transducer 12 configured to excite the substrate with a second frequency f2, which is slightly different compared to the first frequency. Both frequencies are dependent on the dimensions and the structures of the respective transducers. For example, frequency f1 corresponding to wavelength λ1 is dependent on the distance between the metallic electrodes 14 of the two interlocking comb-shaped arrays (in the fashion of a zipper). Basically, the wavelength λ corresponds to the distance between two adjacent electrodes 11a, 11b and 12a, 12b of the same array.

The arrangement further comprises an optoelectronic component 15. The component include a layer stack with an active area arranged between a n-doped first layer and a p-doped second layer. The optoelectronic component is positioned on the surface of the substrate, in which the two layers are substantially perpendicular to the surface of the substrate.

When being exited, the alternating electrical field with the different frequencies induce a propagating surface acoustic wave by varying the polar crystal structure of the material close to the surface. The variation is in the range of less than 4% (probably less than 1%) and depends on the excitation amplitude. The two waves are propagating along the surface and superimpose, inter alia in the area between the two transducers. Under the assumption that both excitation amplitudes y are equal, then the superimposed amplitude yᵣₑₛ(t) of two sinewaves can be expressed as:

$${y}_{r e s} ( t ) = y \cdot sin ( 2 \cdot π \cdot f 1 \cdot t ) + y \cdot sin ( 2 \cdot π \cdot f 2 \cdot t ) \qquad ( 1 )$$

Transforming the equation yields:

$$yres ( t ) = 2 \cdot y \cdot cos ( 2 \cdot π \cdot ( f 1 - f 2 ) / 2 ) \cdot t ) \cdot sin ( 2 \cdot \cdot ( f 1 + f 2 ) / 2 ) \cdot t ) \qquad ( 2 )$$

wherein the term (f1−f2)/2 is the beat frequency; that is the frequency of the enveloping function. The beat frequency is smaller than the two base frequency f1 and f2 and can be adjusted by shifting the two frequencies.

In accordance with the present disclosure, the beat frequency and the wavelength are adjusted to match the thickness of the layer stack of the optoelectronic component. FIGS. 2A and 2B illustrate the electrical field and the interaction with the layer stack at two different times in accordance with some aspects of the present disclosure.

FIG. 2A shows a sideview of the substrate 10 with the optoelectronic component 15 arranged on surface 13. The optoelectronic component 15 is located substantially in the middle of a first interdigital transducer 11 and a second interdigital transducer 12. Each interdigital transducer 11 and 12 comprises a plurality of electrodes 11a, 11b and 12a, 12b, respectively. The distance between electrodes 11a and 12a correspond to the wavelength of the SAW being generated by the transducers.

For simplicity purposes, the transducers 11 and 12 comprise the same dimensions and thus generate a SAW with the same frequency. Considerations on superimpose and the corresponding beat frequency are ignored for simplicity purposes as well. It nevertheless should be noted that one may use slightly different frequencies in order to match the wavelength of the beat signal (the superposition of the respective SAW) with the dimension of the optoelectronic component and increase the maximum amplitude of the E-field and voltage induced.

In FIG. 2A, the resulting electrical or voltage amplitude are illustrated for a dedicated point in time. The electrical field as explained further below extend above the surface of the substrate and comprises a portion having component parallel to the surface 13. Due to this effect, an energy transfer from the alternating electrical field into the optoelectronic component is possible. At the stage shown in FIG. 2A, node N is located directly beneath the active area 151 of the optoelectronic component 15. The maximum positive amplitude +A of field Eb(t1) is located within layer 150 and the negative amplitude −A is located within layer 152. The field Eb(t1) above the surface extend into both layer and exert a force on the free charge carrier towards the active area 151. The amplitude or voltage is high enough that the charge carrier can overcome the internal electrical field in the active area and recombine under emission of light 17. In other words, the optoelectronic component is switched into forward direction and the supplied energy causes an emission.

FIG. 2B illustrates the situation at about half a period later. At this stage, the active area is again located above a node. However, the electrical field Eb(t2) is now pointing in the opposite direction with maximum Amplitude +A now located beneath layer 152. The minimum amplitude −A is located layer 150. The force exerted within the layer stack deplete further charge carriers from the active area, thus effectively switching the optoelectronic component into blocking direction.

The situation illustrated in FIGS. 2A and 2B are valid for propagating SAW but also for standing waves. In the former cases, the nodes are propagating, and thus move periodically along the different layers. Thus, the active area as well as the different layer experience the alternating field. In the latter case with the standing surface acoustic waves, the location of nodes can be predetermined and the optoelectronic component positioned such that the active area is located beneath a node. In such cases, element 12 acts as a reflector and reflects the signal back. Such reflector may also implement by a material boundary.

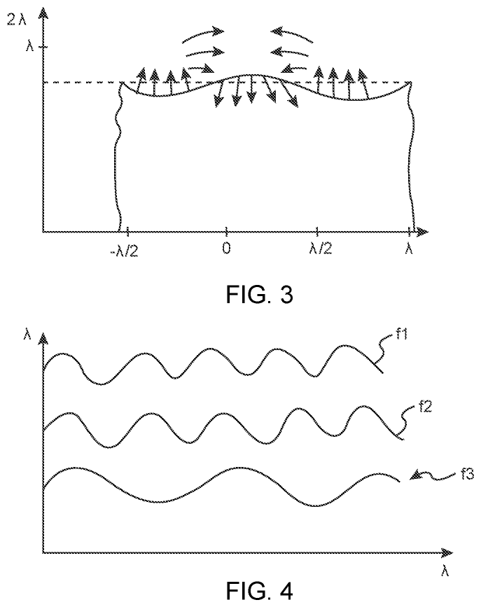

The propagation of the surface acoustic wave is exemplary illustrated in FIG. 3. The SAW may propagate along the surface 13 exploiting the piezoelectric effect. By exciting the substrate comprising a piezoelectric material with an electrical field, the crystal structure changes periodically with the excitation resulting in a wave propagating along the surface by also decaying rapidly within the material. It has been found that the propagating surface acoustic wave is accompanied by a propagating electric field on the piezoelectric substrate. The electrical field as illustrated by the field vectors in FIG. 3 is caused by a slight expansion or compression of the polar material. With a relatively low insertion loss, the field amplitudes can be very high in the order of several V to a few 10 volts. The resulting electrical field extends above the surface and may reach a distance of one or two wavelength before decaying substantially. The field vectors extend from the surface or into the surface. The field vectors can be separated into a component perpendicular and a component parallel to the substrates surface as shown in FIG. 3. Those components are varying and more particularly alternating over time and thus can be used to transfer energy into the semiconductor layers of an optoelectronic component.

FIG. 4 shows two excitation signals with frequencies f1 and f2. Those signals are used by the transducers to generate propagating SAW on the substrate's surface. However, the frequencies f1 and f2 are slightly different, but comprise for the sake of simplicity the same amplitude. When propagating along the surface, the SAWs superimpose each other resulting in an enveloped and superimposed signal. Its frequency is given by the beat frequency (f1−f2)/2 which is usually significantly lower. At the same time, the amplitude of the resulting enveloped and superimposed signal can be expressed as the sum of both individual amplitudes.

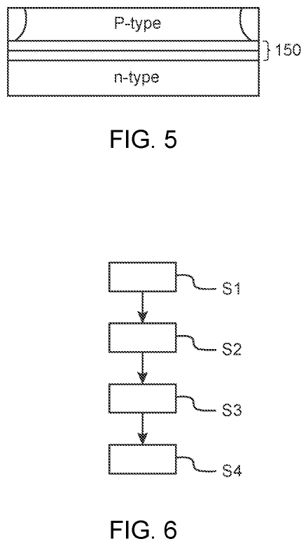

The overall thickness of the optoelectronic component and its relationship of the SAW wavelength (i.e. a superimposed one if such is present) is of importance with regard to efficiency of the arrangement. FIG. 5 illustrates a layer stack suitable to be used as an optoelectronic component. The layer stack comprises an n-type first layer and a p-type second layer. A multi-quantum well structure 150 is arranged between the both layers. Active area 150 may be relatively thin compared to the respective n- or p-doped layers. The thickness as well as the doping profile may depend on the SAW wavelength to ensure a large energy transfer. For example, the both n-type and p-type layer may comprise a relatively large dopant concentration to provide a sufficient amount of free charge carriers in the respective conduction bands. At the same time, thermal generation of charge carriers needs to be at a sufficient level during the relaxation period (i.e. when the electrical field points in the blocking direction. Thus, the dopant profile may vary and differentiate from the profiles used for conventional optoelectronic component supplied by a current.

The thickness of the respective layer is adjusted to match a certain relationship of the SAW wavelength. For example, the thickness of the doped layers is in the range of half of the SAW wavelength, so that the doped layers experience the maximum amplitude when the node of the SAW is beneath the active area. In the present example the p-doped layer also comprises an additional Zn doping close to the edge surface of the structure causing quantum well intermixing in the quantum well layer 150. The bandgap variation by the QWI and the doping profiles causes the charge carrier to be generated and concentrated in the centre of the layer stack increasing efficiency.

FIG. 6 illustrates an example for a method of contactless supplying energy to an optoelectronic component. In step S1, a substrate is provides having piezoelectric properties. On the substrate, an optoelectronic component is arranged in step S2. The optoelectronic component comprises an active area arranged between a first and a second layer of different conductivity types. These preparations steps may be required if surface acoustic waves shall be used to contactless transfer energy into the optoelectronic component. In some embodiment, the optoelectronic component is positioned on the substrate with its first and a second layer substantially perpendicular towards the surface of the substrate.

Then, a surface acoustic wave is generated on the surface of the substrate in steps S3. For this purpose, the substrate is excited with a first frequency causing a SAW to propagate in a first direction with the first frequency. Additionally, the substrate is excited with a second frequency causing a SAW to propagate in a second direction with the second frequency. The propagating waves overlap in an area, causing a superposition of two waves with an enveloping having a beat frequency. The optoelectronic component is positioned in said area.

The SAW comprises an alternating electric field vector that extends above the substrates surface on which the optoelectronic component was arranged in the previous step. More particularly, the electric field caused by the SAW comprises a field component substantially parallel towards the surface of the substrate. The SAW also comprises a wavelength. In step S4, the electric field exerts an alternating force in the first and a second layer of the optoelectronic component with said beat frequency. During a first half-period of the wavelength, charge carriers within the first and a second layer are forced towards the active area and during a second half-period of the wavelength charge carriers within the first and a second layer are forced away from the active area.

1-15. (canceled)

16. An optoelectronic arrangement comprising:
an optoelectronic component comprising a layer stack including an active area arranged between a layer of a first conductive type and a layer of a second conductive type;
a substrate configured to generate an alternating electrical field at a surface of the substrate, the alternating electrical field having opposing field components; and
at least one first excitation element arranged on or within the substrate,
wherein the optoelectronic component is arranged on the substrate such that the opposing field components of the alternating electrical field are substantially perpendicular to respective layers of the layer stack.

17. The arrangement according to claim 16, wherein the substrate is configured to generate a surface acoustic wave propagating beneath the optoelectronic component.

18. The arrangement according to claim 16, wherein at least one of the layers of the first and second conductive types is arranged substantially perpendicular to the surface of the substrate.

19. The arrangement according to claim 16, wherein the opposing field components are spaced apart by a distance corresponding to half of a wavelength of the alternating electrical field.

20. The arrangement according to claim 16, wherein the layer stack comprises a thickness less than a wavelength of the alternating electrical field.

21. The arrangement according to claim 16, wherein the layer stack comprises a thickness in a range of 0.4 to 0.8 of a wavelength of the alternating electrical field.

22. The arrangement according to claim 16, further comprising a second excitation element arranged on or within the substrate spaced apart by a distance from the at least one first excitation element with the optoelectronic component arranged in between.

23. The arrangement according to claim 22, wherein the second excitation element comprises a reflector.

24. The arrangement according to claim 16, wherein the at least one first excitation element and/or a second excitation element comprises an interdigital transducer.

25. The arrangement according to claim 16, wherein the alternating electrical field comprises a standing wave, with the active area of the layer stack being located substantially at a node of the standing wave.

26. The arrangement according to claim 16, wherein at least the first excitation element is configured to excite the substrate with one of the following excitation signals:
a sine wave;
a sawtooth;
a triangle;
a rectangle, optionally with an on/off ratio different from 1; or
a combination thereof.

27. A method for contactless supplying energy to an optoelectronic component, the optoelectronic component having an active area arranged between a first layer and a second layer of different conductivity types, the method comprising:
generating a surface acoustic wave having a wavelength on a surface of a substrate, wherein at least a portion of an electrical field extends above the surface and comprises a field component substantially parallel towards the surface; and
exerting a force by the field component in the first and second layers of the optoelectronic component such that, during a first half-period of the wavelength, charge carriers within the first and second layers are forced towards the active area and, during a second half-period of the wavelength, the charge carriers within the first and second layers are forced away from the active area.

28. The method according to claim 27, further comprising arranging the optoelectronic component on the substrate such that the first and second layers are substantially perpendicular towards the surface of the substrate.

29. The method according to claim 27, wherein generating the surface acoustic wave comprises generating a first surface acoustic wave with a first frequency and generating a second surface acoustic wave with a second frequency that is slightly different from the first frequency.

30. The method according to claim 27, wherein generating the surface acoustic wave comprises adjusting the wavelength such that only one node is located beneath the optoelectronic component.

31. The method according to claim 27, wherein generating the surface acoustic wave comprises generating a standing acoustic wave.
